(19) United States
(12) Patent Application Publication
(10) Pub. No.: US 2025/0120056 A1
(43) Pub. Date: Apr. 10, 2025

(54) PREPARATION DEVICE, MOUNTING DEVICE, MOUNTING SYSTEM, AND INFORMATION PROCESSING METHOD

(71) Applicant: FUJI CORPORATION, Chiryu (JP)

(72) Inventors: Takahiro KOBAYASHI, Chiryu-shi (JP); Kazuya KOTANI, Toyota-shi (JP); Yuki INAURA, Chiryu-shi (JP); Mikiya SUZUKI, Nishio-shi (JP)

(73) Assignee: FUJI CORPORATION, Chiryu (JP)

(21) Appl. No.: 18/727,138

(22) PCT Filed: Jan. 24, 2022
(86) PCT No.: PCT/JP2022/002428

§ 371 Date: Dec. 16, 2024

(51) Int. Cl. H05K 13/08; H05K 13/02

(52) U.S. Cl. CPC H05K 13/0882; H05K 13/02; H05K 13/0812; H05K 13/086

(57) ABSTRACT

A preparation device includes a fixing section configured to fix a component supply device to which a holding member configured to hold a component is attached and feed the holding member, a preparation capturing section configured to capture an image of the holding member fixed to the fixing section, and a preparation control section configured to execute an initial setting process of the holding member by using a captured image captured by the preparation capturing section and cause a storage section to store correspondence information that associates a captured image including a region of the holding member captured by the preparation capturing section in which the component is present and/or a feature value with identification information of the component supply device, and/or correspondence information that associates a captured image including a region of the holding member captured by the preparation capturing section in which the component is not present and/or a feature value with the identification information of the component supply device.

### TECHNICAL FIELD

The present specification discloses a preparation device, a mounting device, a mounting system, and an information processing method.

### BACKGROUND ART

Conventionally, for example, as a mounting device that mounts a component on a processing target such as a board, there has been proposed a device that, when picking up a component stored in a component storage section of a carrier tape with a suction nozzle and transferring the component to a predetermined component mounting position, acquires an image including a current pickup position and a previous pickup position of the component to determine whether the component in the component storage section is a front side based on the acquired image (for example, see Patent Literature 1). With this device, it is possible to quickly determine a state before collecting a component. In addition, as a device used in a mounting system, there has been proposed a device that captures an image of a component accommodating part of a component supply tape at a component pickup position from above to determine an orientation of a component in the component supply tape by using the image (for example, see Patent Literature 2). With this device, when the work of setting the component supply tape in a tape feeder is performed, the orientation of the component can be determined on the component supply tape.

### CITATION LIST

### Patent Literature

Patent Literature 1: JP-A-2014-072409

Patent Literature 2: JP-A-2014-241344

### SUMMARY OF THE INVENTION

### Technical Problem

However, in Patent Literature 1 described above, to determine whether a component is present on the carrier tape serving as a holding member, either an image in which the component is present or an image in which the component is not present may be required. In a mounting device, since what kind of component is provided in a feeder as a component supply device may be changed depending on a mounting process, it is necessary to prepare the image before executing the mounting process. In the mounting device, if the image is acquired at the start of the mounting process, there is a problem in that productivity is reduced because there are a large number of feeders.

The present disclosure has been made in view of such a problem, and a main object thereof is to provide a preparation device, a mounting device, a mounting system, and an information processing method that can further suppress a decrease in efficiency of the mounting process.

### Solution to Problem

A preparation device, a mounting device, a mounting system, and an information processing method disclosed in the present description adopt the following means in order to achieve the main object described above.

A preparation device of the present disclosure is a preparation device used in a mounting system including a mounting device configured to perform a process of mounting a component on a processing target, the preparation device including:
a fixing section configured to fix a component supply device to which a holding member configured to hold the component is attached and feed the holding member;
a preparation capturing section configured to capture an image of the holding member fixed to the fixing section; and
a preparation control section configured to execute an initial setting process of the holding member by using the captured image captured by the preparation capturing section and cause a storage section to store correspondence information that associates a captured image including a region of the holding member captured by the preparation capturing section in which the component is present and/or a feature value with identification information of the component supply device, and/or correspondence information that associates a captured image including a region of the holding member captured by the preparation capturing section in which the component is not present and/or a feature value with the identification information of the component supply device.

This preparation device executes an initial setting process of the holding member by using the captured image captured by the preparation capturing section and prepares the component supply device for use. In addition, the preparation device stores correspondence information that associates the captured image including the region of the holding member in which the component is present or the feature value with the identification information of the component supply device in the storage section. Alternatively, the preparation device stores correspondence information that associates the captured image including the region of the holding member in which the component is not present or the feature value with the identification information of the component supply device in the storage section. Then, with the mounting device, it is possible to use the image and the feature value related to the component associated with the identification information of the component supply device by using the correspondence information stored in this manner, and it is possible to determine the presence or absence of the component of the corresponding component supply device or the like. Accordingly, with this preparation device, it is possible to obtain images and feature values related to the component during the preparation stage of the component supply device without having to capture images during the mounting process. Therefore, with this preparation device, it is possible to further suppress a decrease in efficiency in the mounting process without reducing the cycle time of a demonstration process.

### BRIEF DESCRIPTION OF DRAWINGS

FIG. 1 is a schematic view illustrating an example of a schematic configuration of mounting system 10.

FIG. 2 is a view illustrating an example of a schematic configuration of feeder 50.

FIG. 3 is a view illustrating an example of a schematic configuration of mounting device 15 and loader 18.

FIG. 4 is a view illustrating an example of a schematic configuration of preparation device 40.

FIG. 5 is a view of feeder 50 and preparation capturing section 45 attached to fixing section 44.

FIG. 6 is a view illustrating an example of correspondence information 43 stored in preparation storage section 42.

FIG. 7 is a flowchart illustrating an example of a feeder preparation process routine.

FIGS. 8A and 8B are views for obtaining a captured image and a feature value by feeding holding member 55.

FIG. 9 is a flowchart illustrating an example of a mounting process routine.

FIGS. 10A and 10B are views for obtaining the captured image and the feature value without feeding holding member 55.

### DESCRIPTION OF EMBODIMENTS

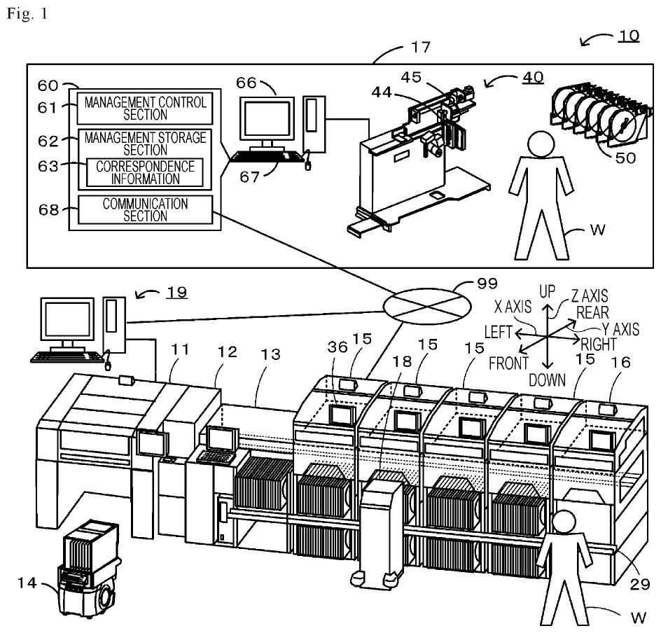

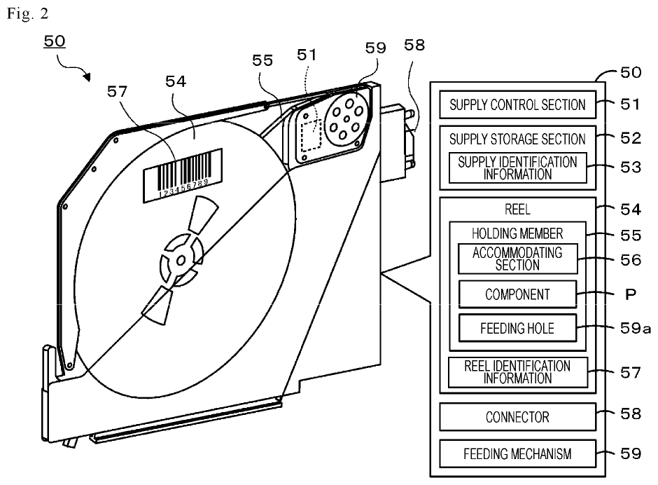

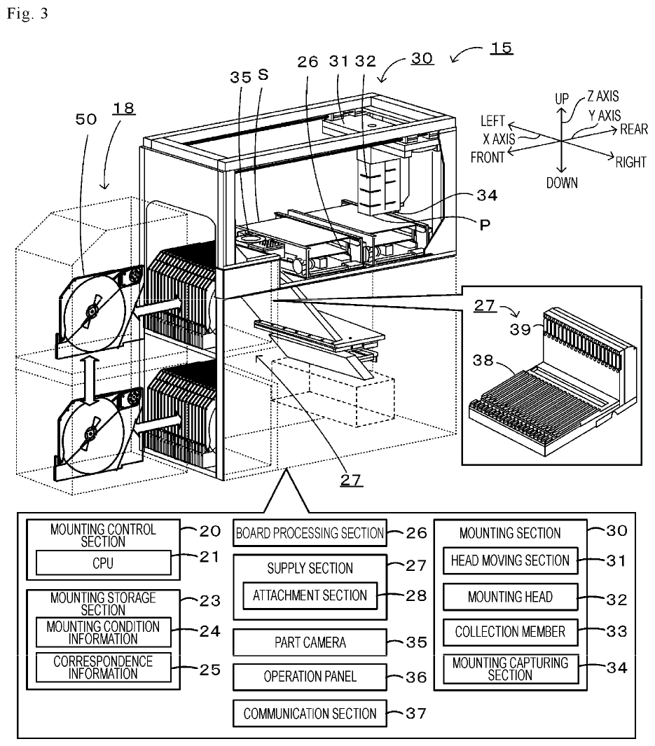

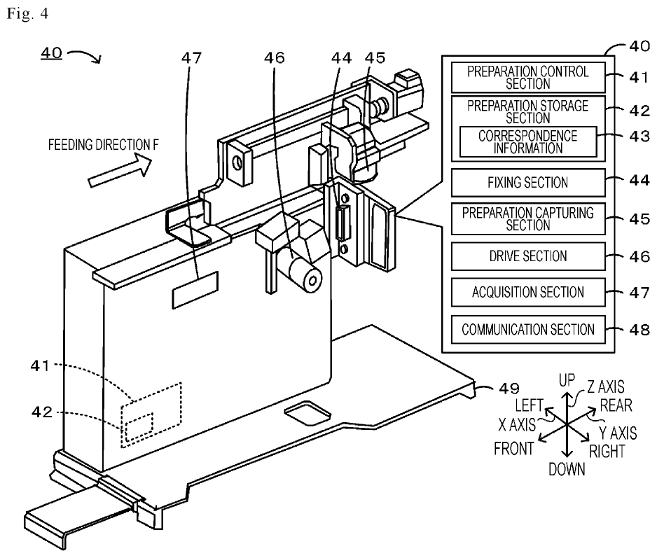

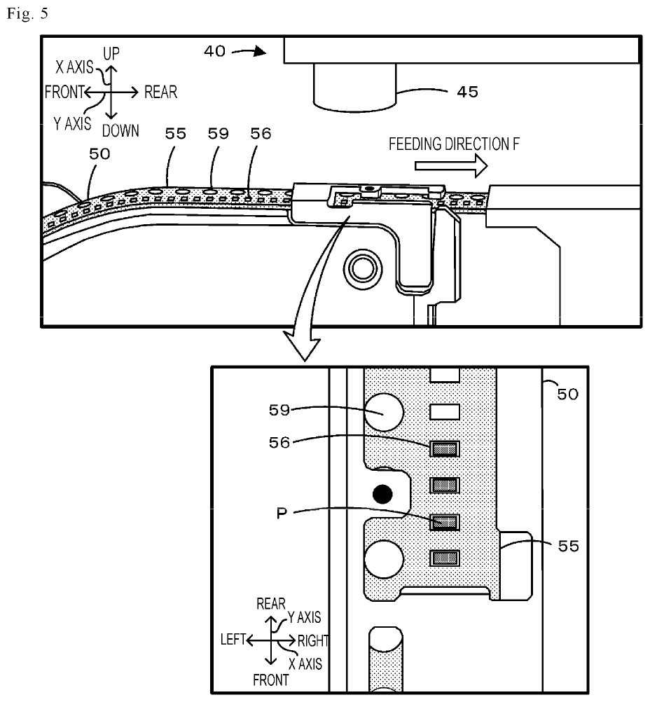

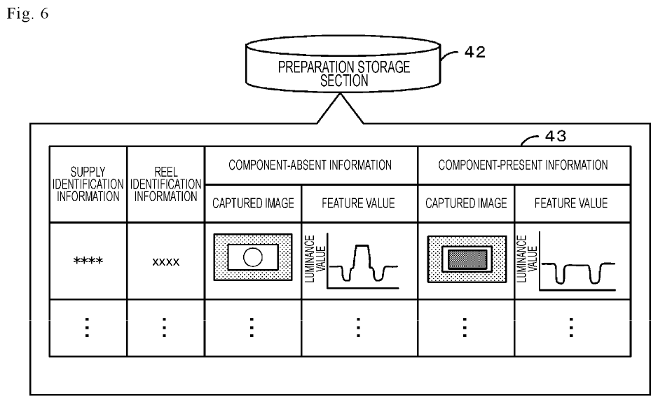

The present embodiment will be described below with reference to drawings. FIG. 1 is a schematic view illustrating an example of mounting system 10 of the present disclosure. FIG. 2 is a view illustrating an example of a schematic configuration of feeder 50. FIG. 3 is a view illustrating an example of a schematic configuration of mounting device 15 and loader 18, which is a mobile work device. FIG. 4 is a view illustrating an example of a schematic configuration of preparation device 40. FIG. 5 is a view of feeder 50 and preparation capturing section 45 attached to fixing section 44. FIG. 6 is a view illustrating an example of correspondence information 43 stored in preparation storage section 42. In the present embodiment, a left-right direction (an X axis), a front-rear direction (a Y axis), and an up-down direction (a Z axis) are as illustrated in FIGS. 1, 3 to 5.

Mounting system 10 is configured, for example, as a production line in which mounting devices 15 performing a process of mounting components P on board S serving as a processing target are arranged in a conveyance direction of board S. Here, the processing target will be described as board S, but the processing target is not particularly limited as long as the processing target is an object on which component is mounted, and may be a board having a three-dimensional shape. As illustrated in FIG. 1, mounting system 10 includes printing device 11, printing inspection device 12, storage device 13, automatic conveyance vehicle 14, mounting device 15, mounting inspection device 16, preparation facility 17, loader 18, overall control device 19, and the like. Printing device 11 is a device that prints viscous fluid such as a solder paste on board S. Printing inspection device 12 is a device that inspects a state of printed solder or board S. Storage device 13 is a storage place for temporarily storing feeder 50 used in mounting device 15. Storage device 13 is provided adjacent to a conveyance device between printing inspection device 12 and mounting device 15. Automatic conveyance vehicle 14 automatically conveys feeder 50, members used in mounting system 10, or the like between storage device 13 disposed in the production line and preparation facility 17. Automatic conveyance vehicle 14 is configured as, for example, an automatic guided vehicle (AGV) or an autonomous mobile robot (AMR). Mounting inspection device 16 is a device that inspects a state of component P disposed on board S.

Loader 18 is a mobile work device, and is a device that moves along X-axis rail 29 disposed on the front surface of mounting system 10 and automatically collects or replenishes feeder 50 of mounting device 15. Loader 18 includes a movement control section that causes the entire device to collect feeder 50 from supply section 27 or replenish feeder 50 to supply section 27 and move feeder 50 to and from storage device 13. Overall control device 19 is configured as a server that creates and manages information used by each device of mounting system 10, for example, production plan information. In mounting system 10, each device exchanges information via network 99 serving as an electric communication line such as a LAN or the Internet.

Feeder 50 is a tape feeder configured as a cassette type component supply device that accommodates reel 54. As illustrated in FIG. 2, feeder 50 includes supply control section 51, supply storage section 52, reel 54, connector 58, and feeding mechanism 59. Supply control section 51 is a controller that controls the entire device. Supply storage section 52 is a storage medium in which information can be written and deleted, and examples thereof include a flash memory. Supply identification information 53 for identifying feeder 50 is stored in supply storage section 52. Supply identification information 53 is an ID for specifying feeder 50, and includes an individual character string assigned to each feeder in advance. Supply storage section 52 stores information such as the component type and the number of remaining components held by holding member 55 in association with supply identification information 53. Reel 54 is a member around which a tape serving as holding member 55 is wound, and is detachably attached to feeder 50. Reel identification information 57 is attached to the outer peripheral surface of reel 54. Reel identification information 57 is an ID that specifies reel 54 and that is associated with the type of component P to be held, and includes an individual character string or the like assigned in advance for each reel. Reel identification information 57 may be a bar code or a two-dimensional code. Pocket-shaped accommodating sections 56 are formed at predetermined intervals in holding member 55, and components P are held in accommodating sections 56. Further, feeding holes 59a into which the distal ends of sprockets of feeding mechanism 59 are inserted are formed at equal intervals in holding member 55. Connector 58 is a connection member that is electrically attached to attachment section 28 provided in supply section 27 of mounting device 15 or an attachment section provided in fixing section 44 of preparation device 40. When connector 58 is attached to the attachment section, communication between supply control section 51 and external devices becomes possible. Feeding mechanism 59 feeds holding member 55 along feeding direction F. Feeding mechanism 59 includes a thin drive motor and a sprocket connected to the drive motor via a gear. Feeder 50 is prepared to be usable by preparation device 40 or worker W in preparation facility 17.

Mounting device 15 is a device that collects component P and mounts component P on board S. As illustrated in FIG. 3, mounting device 15 includes mounting control section 20, mounting storage section 23, board processing section 26, supply section 27, mounting section 30, part camera 35, and communication section 37. Mounting control section 20 is configured as a microprocessor centered on CPU 21, and controls the entire device. Mounting control section 20 outputs control signals to board processing section 26, supply section 27, mounting section 30, part camera 35, and the like, and inputs signals from board processing section 26, supply section 27, mounting section 30, and part camera 35. Mounting storage section 23 stores mounting condition information 24, correspondence information 25, and the like. Mounting condition information 24 is a production job, and includes information on component P, information on a disposition order and a disposition position for mounting components P on board S, and an attachment position of feeder 50 for collecting a component. A collection order, a disposition order, and the like having high mounting efficiency are created by overall control device 19, and mounting condition information 24 is transmitted from overall control device 19 and stored in mounting storage section 23. Correspondence information 25 is associated with supply identification information 53 of feeder 50 currently attached to supply section 27, reel identification information 57 of reel 54 in feeder 50, the component type and the number of remaining components held by holding member 55, the captured image and/or the feature value of holding member 55 in which component P is not present, the captured image and/or the feature value of holding member 55 in which component P is present, and the like. Correspondence information 25 includes the same contents as correspondence information 43 (see FIG. 6) created by preparation device 40, and is transmitted from preparation device 40 to management PC 60, overall control device 19, and mounting device 15 and stored in each device.

Board processing section 26 is a unit that performs carrying in, conveyance, fixation of board S at a mounting position, and carrying out thereof. Board processing section 26 has a pair of conveyor belts provided at intervals in the front-rear direction and spanning the left-right direction. Board S is conveyed by the conveyor belts. Supply section 27 is a unit that supplies a component to mounting section 30. Supply section 27 attaches feeder 50 as a component supply device to one or more attachment sections. As illustrated in FIG. 3, supply section 27 has two upper and lower attachment sections in which feeders 50 can be attached in front. The upper part is attachment section 28 for mounting from which a component can be collected by mounting section 30, and the lower part is a buffer attachment section from which a component cannot be collected by mounting section 30. Feeder 50 from which a component is collected by mounting head 32 is attached to attachment section 28. Supply section 27 is provided with an attachment section that includes multiple slots 38 arranged in the X direction at predetermined intervals and into which rail members of feeder 50 are inserted and connection section 39 into which connector 58 provided at the tip of feeder 50 is inserted.

Mounting section 30 is a unit that executes a mounting process of collecting component P from feeder 50 attached to attachment section 28 of supply section 27 and disposing component P on board S fixed to board processing section 26. Mounting section 30 includes head moving section 31, mounting head 32, collection member 33, and mounting capturing section 34. Head moving section 31 includes a slider moving by being guided by guide rails in the XY directions, and a motor that drives the slider. Mounting head 32 collects one or more components P and is moved in the XY directions by head moving section 31. Mounting head 32 is detachably attached to the slider. Nozzles as one or more collection members 33 are detachably attached to the lower surface of mounting head 32. The nozzles are configured to collect component P by making use of a negative pressure. Collection member 33 for collecting component P may be a mechanical chuck for mechanically holding component P instead of the nozzle. Mounting capturing section 34 is disposed on the lower surface side of mounting head 32. Mounting capturing section 34 is a mark camera that moves in the XY directions according to the movement of mounting head 32 and captures an image of a mark formed on board S. Mounting capturing section 34 captures an image of holding member 55 attached to attachment section 28 at a position where component P of supply section 27 is collected, in addition to the mark on board S.

Part camera 35 is a device that captures an image of one or more components P, which are collected and held by mounting head 32, from below. When mounting head 32 that has collected component P passes above part camera 35, part camera 35 captures an image of component P and outputs the captured image to mounting control section 20. Mounting control section 20 detects a collection state of component P by using the captured image. Operation panel 36 is a unit that exchanges information with a worker, and includes a display section for displaying a screen and an operation section for worker W to operate. Communication section 37 is an interface for exchanging information with external devices such as preparation device 40, overall control device 19, or management PC 60. Mounting device 15 is connected to external devices such as preparation device 40 and overall control device 19 via network 99 serving as an electric communication line connected to communication section 37.

Preparation facility 17 is an area for preparing exchangeable members such as consumables used in mounting system 10 and the like. Preparation facility 17 is a warehouse and stores reel 54, feeder 50, or the like. In preparation facility 17, worker W sets reel 54 on feeder 50 to use mounting device 15, and uses preparation device 40 to prepare feeder 50 for use. As illustrated in FIG. 1, in preparation facility 17, preparation device 40 and management PC 60 are disposed. Management PC 60 is a device that manages work at preparation facility 17, and includes management control section 61, management storage section 62, display section 66, input device 67, and communication section 68. Management control section 61 is configured as a microprocessor centered on CPU and controls the entire device. Management storage section 62 stores correspondence information 63 similar to correspondence information 43 created by preparation device 40 or the like. Display section 66 is a liquid crystal screen that displays various types of information. Input device 67 includes a keyboard, a mouse, and the like through which worker W inputs various commands. Communication section 68 is an interface that performs communication with external devices. Worker W attaches reel 54 to empty feeder 50 based on the information displayed on display section 66. In addition, worker W performs work of attaching feeder 50 to which reel 54 is attached to fixing section 44 of preparation device 40. In preparation device 40, the preparation work is executed to make feeder 50 usable in mounting device 15.

Preparation device 40 is a device used in mounting system 10 including mounting device 15. Preparation device 40 is configured as a kitting stand on which feeder 50 is attached to and which performs a process of associating supply identification information 53 and reel identification information 57 and an initial setting process of component P. In addition, preparation device 40 is a device that acquires and stores the captured image with or without component P for each feeder 50 and the feature value thereof. As illustrated in FIG. 4, preparation device 40 includes preparation control section 41, preparation storage section 42, fixing section 44, preparation capturing section 45, drive section 46, acquisition section 47, communication section 48, and preparation table 49. Preparation control section 41 is a controller that controls the entire device. Preparation storage section 42 is a large-capacity, writable, deletable storage medium, and examples thereof include a flash memory. Preparation storage section 42 stores correspondence information 43. In correspondence information 43, as illustrated in FIG. 6, supply identification information 53, reel identification information 57, the captured image with no component and the feature value thereof, and the captured image with a component and the feature value thereof are associated with each other. Examples of the feature value of the captured image include a luminance value and a variance thereof. Fixing section 44 is attached with holding member 55 that holds component P, and fixes feeder 50 as a component supply device that feeds holding member 55. Fixing section 44 is electrically connectable to feeder 50 and has the same configuration as that of attachment section 28 described above. Preparation capturing section 45 is a camera that images holding member 55 fixed to fixing section 44. Preparation capturing section 45 is configured to be moved back and forth along feeding direction F along a guide. As illustrated in FIG. 5, preparation capturing section 45 images holding member 55 at the tip of feeder 50. Drive section 46 is a motor externally connected to feeding mechanism 59 of feeder 50. Drive section 46 rotates feeding mechanism 59 from the outside to feed holding member 55 along feeding direction F. Acquisition section 47 is configured as a code reader that reads and acquires reel identification information 57 attached to reel 54. Acquisition section 47 is disposed on the side surface side of a main body of preparation device 40, and reads reel identification information 57 disposed on the side surface of feeder 50. Preparation device 40 may include acquisition section 47 of a mobile handy scanner, and worker W may read reel identification information 57 by the handy scanner. Communication section 48 is an interface that exchanges information with external devices such as management PC 60, overall control device 19, mounting device 15, or the like. Preparation table 49 is a table on which feeder 50 is placed and slid. Preparation table 49 is configured such that feeders 50 having various thicknesses can be placed thereon.

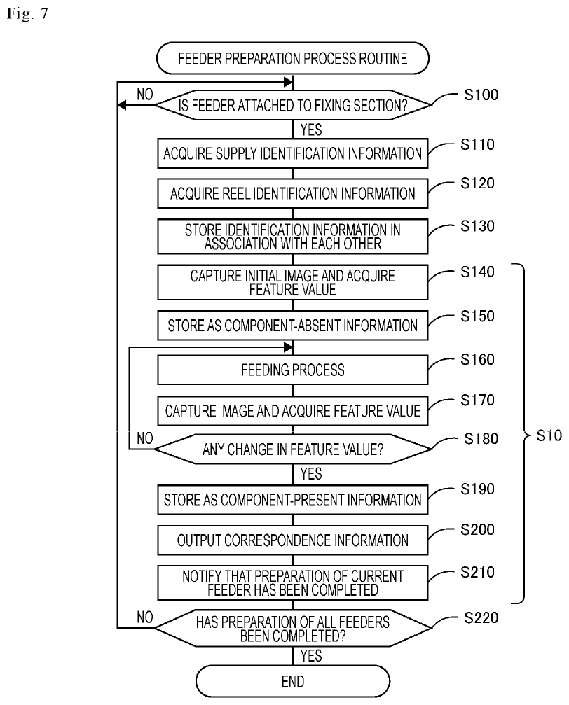

Next, an operation of mounting system 10 of the present embodiment configured as described above, that is, first, a preparation process for making feeder 50 usable in mounting device 15 will be described. Based on mounting condition information 24 executed by mounting device 15, overall control device 19 outputs, to management PC 60, information relating to the component type used most recently by mounting device 15 and feeder 50 to be used. In preparation facility 17, worker W attaches corresponding reel 54 to empty feeder 50 based on the instruction displayed on display section 66 of management PC 60. Then, worker W attaches feeder 50 to fixing section 44 of preparation device 40. FIG. 7 is a flowchart illustrating an example of a feeder preparation process routine executed by preparation control section 41 of preparation device 40. This routine is stored in preparation storage section 42 of preparation device 40 and executed before the start of the production process of mounting device 15.

When this routine is started, preparation control section 41 first determines whether feeder 50 is attached to fixing section 44 (S100). When feeder 50 is not attached to fixing section 44, preparation control section 41 stands by. On the other hand, when feeder 50 is attached to fixing section 44, supply identification information 53 stored in supply storage section 52 is acquired (S110). When feeder 50 is attached to fixing section 44 and a request is received from preparation control section 41, supply control section 51 reads supply identification information 53 from supply storage section 52 and outputs the read information to preparation device 40. Next, preparation control section 41 causes acquisition section 47 to read and acquire reel identification information 57 (S120). Next, preparation control section 41 stores acquired supply identification information 53 and reel identification information 57 in association with each other as correspondence information 43 in preparation storage section 42 (S130). Correspondence information 43 is transmitted to mounting device 15 later, and is used for specifying feeder 50 attached to attachment section 28 and specifying the component type.

Next, preparation control section 41 executes an initial setting process of feeder 50 (S10, S140 to S210). Specifically, preparation control section 41 moves preparation capturing section 45 above holding member 55 at the tip of feeder 50, causes preparation capturing section 45 to capture a first captured image, and acquires the feature value of the image (S140). In holding member 55, some of accommodating sections 56 is empty at the tip thereof. Preparation control section 41 causes preparation storage section 42 to store the captured image including the region of holding member 55 in which component P is not present and the feature value as information indicating that there is no component (S150). Next, preparation control section 41 causes drive section 46 to execute a process of feeding holding member 55 (S160), causes preparation capturing section 45 to capture an image, and acquires a feature value of the image (S170). Subsequently, preparation control section 41 determines whether there is a change from a previous feature value (S180). Preparation control section 41 determines whether the feature value has changed beyond a predetermined threshold empirically obtained based on the presence or absence of component P. When there is no change from the previous feature value, it is determined that accommodating section 56 is empty, and the processes from S160 and subsequent steps is repeatedly executed. On the other hand, when there is a change from the previous feature value in S180, preparation control section 41 stores the captured image including the region of holding member 55 where there is component P and the feature value in preparation storage section 42 as information indicating that there is a component (S190). Preparation control section 41 stores information indicating that there is no component and information indicating that there is a component in correspondence information 43 in association with supply identification information 53 (see FIG. 6).

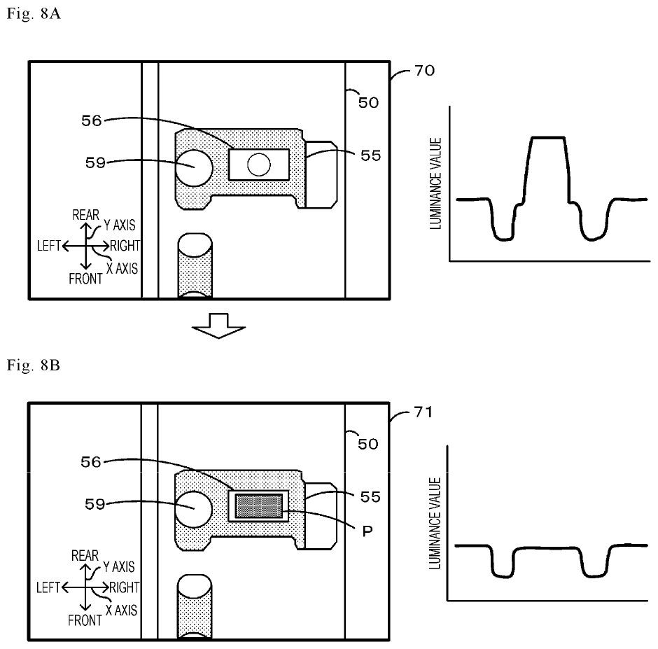

FIGS. 8A and 8B are views for obtaining a captured image and a feature value by feeding holding member 55, FIG. 8A is a view of component-absent captured image 70 with no component and the feature value thereof, and FIG. 8B is a view of component-present captured image 71 with a component and the feature value thereof. Here, a case where component P has a surface with a low luminance value and empty accommodating section 56 indicates a high luminance value will be described as an example. As illustrated in FIGS. 8A and 8B, when a transition is made from accommodating section 56 having no component P to accommodating section 56 having component P, the pattern of the luminance value changes. Based on the change in the feature value, preparation control section 41 acquires component-absent captured image 70 and the feature value thereof, and component-present captured image 71 and the feature value thereof, and stores the same in preparation storage section 42.

After S190, preparation control section 41 outputs stored correspondence information 43 to management PC 60 (S200). Management PC 60 stores correspondence information 43 as correspondence information 63, and then outputs the same to overall control device 19 or mounting device 15. Subsequently, preparation control section 41 outputs information to management PC 60 to notify worker W that the preparation of feeder 50 attached to fixing section 44 has been completed, indicating that the initial setting process for component P of feeder 50 has been completed (S210). At this time, preparation device 40 may cut off unnecessary portions of fed holding member 55 by using a cutter (not shown). Management PC 60 causes display section 66 to display a screen indicating that the preparation of feeder 50 has been completed. Worker W confirms this screen and removes feeder 50 from preparation device 40. After S210, preparation control section 41 determines whether the preparation of all feeders 50 has been completed (S220), and when the preparation of all feeders 50 has not been completed, executes the processes from S100 and subsequent steps. On the other hand, when the preparation of all feeders 50 has been completed in S220, this routine is ended. Thus, in preparation facility 17, the preparation work of feeder 50 to be used next is performed.

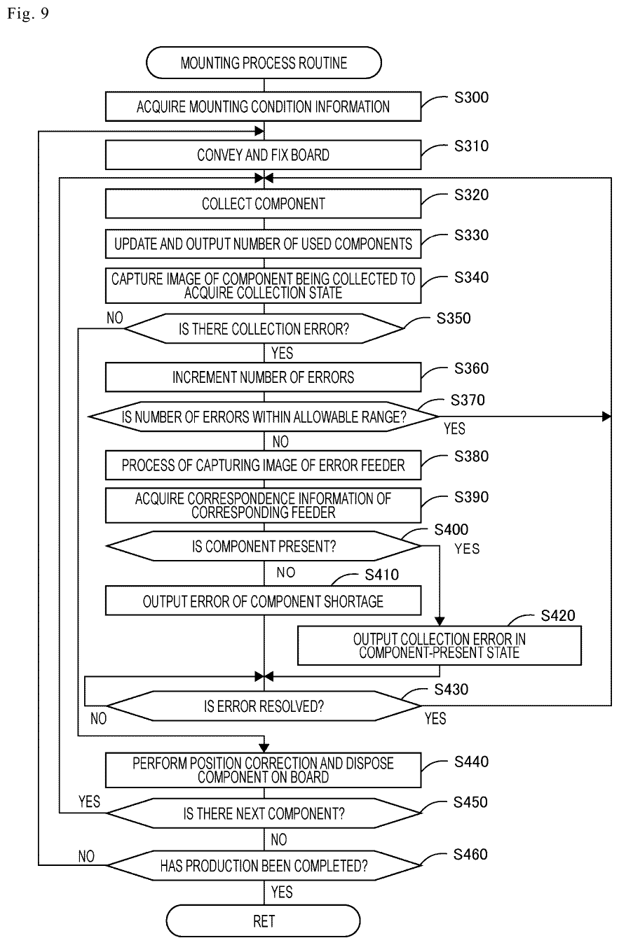

Next, the mounting process in which mounting device 15 disposes component P on board S will be described. Mounting device 15 acquires correspondence information 43 from management PC 60 or the like, and stores the same as correspondence information 25 in mounting storage section 23. In addition, feeders 50 prepared in preparation facility 17 are conveyed by automatic conveyance vehicle 14 and loader 18, and are respectively attached to attachment sections 28 based on mounting condition information 24. Mounting control section 20 of mounting device 15 acquires supply identification information 53 stored in supply storage section 52 from feeder 50 via attachment section 28, and specifies attached feeder 50 and the component type thereof. FIG. 9 is a flowchart illustrating an example of a mounting process routine executed by CPU 21 of mounting control section 20. This routine is stored in mounting storage section 23, and is executed together with a start command of the mounting process by worker W.

When this routine is started, CPU 21 first reads and acquires mounting condition information 24 of board S to be produced this time (S300). CPU 21 reads mounting condition information 24 acquired from overall control device 19 and stored in mounting storage section 23. Next, CPU 21 causes board processing section 26 to convey and fix board S to the mounting position (S310). Next, CPU 21 causes mounting head 32 to collect component P (S320). Next, CPU 21 updates the number of used components P in correspondence information 25, and outputs updated correspondence information 25 to overall control device 19 (S330). Overall control device 19 outputs information prompting management PC 60 to prepare next feeder 50 when the number of remaining components P in feeder 50 falls below a predetermined number of preparations to start.

Next, CPU 21 causes part camera 35 to capture an image of component P that is being collected by mounting head 32 to acquire the collection state of component P (S340). CPU 21 can acquire the collection state of component P by analyzing the captured image. Next, CPU 21 determines whether there is a collection error in which component P has not been able to be collected (S350). When there is no collection error, CPU 21 performs position correction according to the collection state acquired in S340 and disposes component P on board S (S440). Then, CPU 21 determines whether there is a component to be collected next based on mounting condition information 24 (S450). When there is component P to be collected next, CPU 21 repeatedly executes the processes from S320 and subsequent steps. That is, CPU 21 causes mounting head 32 to collect component P, performs position correction while determining whether there is a collection error of component P, and disposes component P on board S.

On the other hand, when there is a collection error in S350, CPU 21 increments the number of errors of feeder 50 corresponding to the collection error by 1 (S360), and determines whether the number of errors is within an allowable range (S370). This allowable range is determined by the number of retries for collecting component P, and can be set to, for example, three times or five times. When the number of errors is within the allowable range, CPU 21 executes the processes from S320 and subsequent steps as an accidental collection error. On the other hand, when the number of errors is outside the allowable range in S370, CPU 21 causes mounting capturing section 34 to capture an image of the collection position of feeder 50 where the corresponding collection error has occurred, indicating that feeder 50 is short of components or the collection error is due to an error in feeder 50 or mounting section 30 (S380). Subsequently, CPU 21 reads and acquires correspondence information 25 of corresponding feeder 50 from mounting storage section 23 (S390) to determine whether component P remains in holding member 55 based on the captured image and correspondence information 25 (S400). CPU 21 determines whether the image and/or the feature value of the collection region of the captured image corresponds to the component-absent information or the component-present information stored in correspondence information 25 (see FIG. 6). Since CPU 21 uses correspondence information 25 including the captured image of holding member 55, it is possible to more accurately determine the presence or absence of component P.

When component P is not present in holding member 55 in S400, CPU 21 outputs information indicating that an error of component shortage has occurred to overall control device 19 and operation panel 36 (S410). In mounting device 15, when reels 54 having different numbers of components are used in the preparation stage, an error of component shortage may occur. Overall control device 19 that has received this error of component shortage causes loader 18 to automatically replace feeder 50 when there is substitute feeder 50 in storage device 13 or buffer attachment section 28. On the other hand, when there is no substitute feeder 50 in storage device 13, information for preparing next feeder 50 is output to management PC 60. On the other hand, when component P is present in holding member 55 in S400, CPU 21 outputs information to operation panel 36, indicating that a collection error of a component-present state has occurred (S420). After confirming operation panel 36, worker W confirms whether there is any failure with mounting section 30 and feeder 50. In mounting device 15, for example, a collection error of the component-present state may occur due to a failure in attaching feeder 50 or collection member 33. When there is a failure, worker W handles the failure.

After S420 or S410, CPU 21 determines whether the error is resolved (S430). When the error has not been resolved, CPU 21 remains on standby, and when the error has been resolved, CPU 21 executes the processes from S320 and subsequent steps. That is, CPU 21 returns to the normal processing. Then, when there is no next component P to be disposed on this board S in S450, CPU 21 determines whether the production of board S has been completed (S460). When the production is not completed, the processes from S310 and subsequent steps, that is, board S is discharged, next board S is conveyed and fixed, and the mounting process is executed. On the other hand, when the production is completed in S460, this routine ends. In this manner, mounting device 15 executes the mounting process of component P while determining the presence of component P based on the captured image in the event of an error.

Here, a correspondence relationship between the elements of the present embodiment and the elements of the present disclosure will be clarified. Preparation device 40 of the present embodiment corresponds to a preparation device, fixing section 44 corresponds to a fixing section, preparation capturing section 45 corresponds to a preparation capturing section, mounting storage section 23, preparation storage section 42, and management storage section 62 correspond to a storage section, and preparation control section 41 corresponds to a preparation control section. In addition, mounting device 15 corresponds to a mounting device, mounting control section 20 corresponds to a mounting control section, attachment section 28 corresponds to an attachment section, mounting section 30 corresponds to a mounting section, and mounting capturing section 34 corresponds to a mounting capturing section. Further, component P corresponds to a component, board S corresponds to a processing target, holding member 55 corresponds to a holding member, feeder 50 corresponds to a component supply device, mounting system 10 corresponds to a mounting system, component-absent captured image 70 and component-present captured image 71 correspond to captured images, correspondence information 25, correspondence information 43, and correspondence information 63 correspond to correspondence information, supply storage section 52 corresponds to a supply storage section, and network 99 corresponds to an electric communication line. In the present embodiment, an example of the information processing method of the present disclosure is also made clear by describing the operations of preparation device 40 and mounting device 15.

Preparation device 40 described above includes fixing section 44 that fixes feeder 50 as a component supply device to which holding member 55 holding component P is attached and feeds holding member 55, preparation capturing section 45 that captures an image of holding member 55 fixed to fixing section 44, and preparation control section 41 that executes an initial setting process of holding member 55 by using the captured image captured by preparation capturing section 45 and that causes preparation storage section 42 to store correspondence information 43 that associates the captured image including the region of holding member 55 in which component P whose image has been captured by preparation capturing section 45 is present and/or a feature value with supply identification information 53. In addition, preparation control section 41 causes preparation storage section 42 to store correspondence information 43 that associates the captured image including the region of holding member 55 in which component P whose image has been captured by preparation capturing section 45 is not present and/or the feature value with supply identification information 53. Preparation device 40 performs the initial setting process of holding member 55 by using the captured image captured by preparation capturing section 45 to prepare feeder 50 for use. Further, in preparation device 40, correspondence information 43 that associates the captured image of holding member 55 with supply identification information 53 is stored in preparation storage section 42, management storage section 62, mounting storage section 23, or the like. Then, with mounting device 15, by using correspondence information 25 stored in this manner, it is possible to use the captured image and the feature value regarding component P associated with supply identification information 53 of feeder 50, and it is possible to determine the presence or absence of component P of corresponding feeder 50 or the like. Accordingly, in preparation device 40, it is possible to obtain the captured image and feature value regarding component P or the like in the preparation stage of feeder 50, without capturing an image for determining the presence or absence of component P during the mounting process. Therefore, with this preparation device 40, the cycle time of the mounting process is not reduced, and a decrease in efficiency in the mounting process can be further suppressed.

In addition, preparation control section 41 causes preparation storage section 42 and the like to store the captured image captured by preparation capturing section 45 as a captured image including the region of holding member 55 in which component P is not present, and causes preparation storage section 42 to store a captured image in which the feature value of the image captured by feeding holding member 55 has changed as a captured image including the region of holding member 55 in which component P is present. In this preparation device 40, it is possible to acquire the captured image and feature value indicating whether component P is present in holding member 55 according to a change in the feature value. Further, feeder 50 includes supply storage section 52 that stores supply identification information 53 of feeder 50, fixing section 44 can be electrically connected to feeder 50, and preparation control section 41 acquires supply identification information 53 output from supply storage section 52. With this preparation device 40, supply identification information 53 can be acquired more reliably. Further, preparation control section 41 acquires reel identification information 57 of holding member 55 and supply identification information 53 of feeder 50, and causes preparation storage section 42 to store reel identification information 57 and supply identification information 53 in association with each other as correspondence information 43. In this preparation device 40, feeder 50 can be prepared for use by associating the identification information of holding member 55 with the identification information of feeder 50.

In addition, attachment section 28 that is connected to mounting device 15 and preparation device 40 via network 99 as an electric communication line and that attaches feeder 50, mounting capturing section 34 that captures an image of holding member 55 attached to attachment section 28, mounting section 30 that executes the mounting process of collecting component P from feeder 50 attached to attachment section 28 and disposes the same on board S as a processing target, and mounting control section 20 that acquires correspondence information 25 corresponding to feeder 50 attached to attachment section 28 from mounting storage section 23 to determine whether component P remains in feeder 50 based on acquired correspondence information 25 and the captured image captured by mounting capturing section 34 are provided. Then, in mounting device 15, by using correspondence information 25 stored by preparation device 40 described above, it is possible to use the captured image and feature value regarding component P associated with supply identification information 53 of feeder 50, and it is possible to determine the presence or absence of component P of corresponding feeder 50 or the like. Accordingly, in this mounting device 15, it is possible to further suppress a decrease in efficiency in the mounting process without capturing an image for determining the presence or absence of component P during the mounting process. In addition, after a collection error of component P occurs due to mounting section 30, mounting control section 20 determines whether component P remains in feeder 50 in which the collection error has occurred. In this mounting device 15, it is possible to determine the presence or absence of component P provided in feeder 50 after the collection error. For example, in mounting device 15 including loader 18, feeder 50 in which a collection error has occurred may be moved to storage device 13 regardless of the presence or absence of component P. In this mounting device 15, even feeder 50 in which a collection error has occurred can be used without collecting.

Further, mounting system 10 includes preparation device 40 described above and mounting device 15 described above. Since this mounting system 10 includes preparation device 40 described above and mounting device 15 described above, it is possible to further suppress a decrease in efficiency in the mounting process.

It is obvious that the present disclosure is not limited to the embodiment described above, and can be practiced in various aspects as long as the aspects belong to the scope of the present invention.

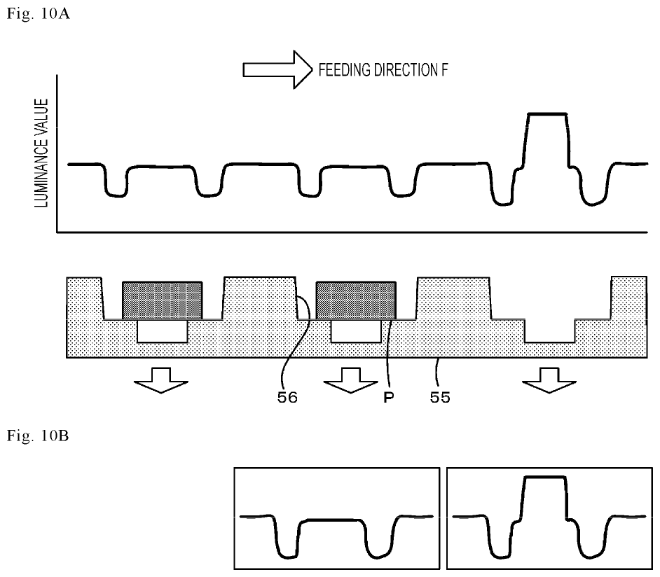

For example, in the embodiment described above, preparation device 40 feeds holding member 55 to acquire a captured image in which component P is not present and a captured image in which component P is present, but the present invention is not particularly limited thereto. FIGS. 10A and 10B are views for obtaining a captured image and a feature value without feeding holding member 55. For example, when there is no member above accommodating section 56, preparation device 40 can move preparation capturing section 45 to capture an image of holding member 55. In this case, preparation control section 41 obtains a captured image in which component P is not present on the distal end side in feeding direction F. Preparation control section 41 can determine that the region after the feature value is changed is a captured image in which component P is present.

In the embodiment described above, a captured image in which component P is not present, a feature value in which component P is not present, a captured image in which component P is present, and a feature value in which component P is present are stored as correspondence information 43 that is associated with supply identification information 53, but one or more of these images and feature values may be omitted. With mounting device 15, it is possible to determine the presence or absence of component P depending on whether the image captured by mounting capturing section 34 matches one of these images and feature values.

In the embodiment described above, the captured image captured in the initial setting process of holding member 55 is stored in correspondence information 43, but the present invention is not particularly limited thereto, and the captured image may be obtained separately from the initial setting process. Note that, in preparation device 40, it is preferable to use the captured image captured in the initial setting process because work efficiency is high.

In the embodiment described above, in addition to the correspondence relationship between supply identification information 53 and reel identification information 57, preparation device 40 uses correspondence information 43 that associates the captured image and/or the feature value with supply identification information 53, but the present invention is not particularly limited thereto, and may manage the information as separate information.

In the embodiment described above, mounting device 15 determines whether component P remains in feeder 50 after the collection error based on correspondence information 25 and the image captured by mounting capturing section 34, but the present invention is not particularly limited thereto, and this determination may be made at times other than when a collection error occurs. Also in this mounting device 15, since the captured image of feeder 50 is used, it is possible to more reliably determine whether component P remains in feeder 50.

In the embodiment described above, the present disclosure is applied to the forms of mounting system 10, preparation device 40, and mounting device 15 but the present disclosure may be applied to the information processing method, and a program causing a computer to execute respective steps of the information processing method may be applied.

Here, the information processing method of the present disclosure may be configured as follows. For example, the information processing method of the present disclosure is an information processing method executed by a preparation device used in a mounting system including a mounting device configured to perform a process of mounting a component on a processing target and having a fixing section configured to fix a component supply device to which a holding member configured to hold the component is attached and feed the holding member and a preparation capturing section configured to capture an image of the holding member fixed to the fixing section, the information processing method including:
(a) a step of executing an initial setting process of the holding member by using a captured image captured by the preparation capturing section; and
(b) a step of storing correspondence information that associates a captured image including a region of the holding member captured by the preparation capturing section in which the component is present and/or a feature value with identification information of the component supply device, and/or correspondence information that associates a captured image including a region of the holding member captured by the preparation capturing section in which the component is not present and/or a feature value with the identification information of the component supply device in a storage section.

With this information processing method, since it is possible to obtain the image and feature value regarding a component or the like in the preparation stage of the component supply device without capturing an image during the mounting process of the mounting device, it is possible to further suppress a decrease in efficiency in the mounting process. In this information processing method, various aspects of the preparation device and/or mounting device described above may be adopted, or steps may be added to achieve each function of the preparation device and/or mounting device described above.

### INDUSTRIAL APPLICABILITY

The present disclosure is applicable to the technical field of a device that collects and mounts a component.

### REFERENCE SIGNS LIST

10 mounting system, 11 printing device, 12 printing inspection device, 13 storage device, 14 automatic conveyance vehicle, 15 mounting device, 16 mounting inspection device, 17 preparation facility, 18 loader, 19 overall control device, 20 mounting control section, 21 CPU, 23 mounting storage section, 24 mounting condition information, 25 correspondence information, 26 board processing section, 27 supply section, 28 attachment section, 29 X-axis rail, 30 mounting section, 31 head moving section, 32 mounting head, 33 collection member, 34 mounting capturing section, 35 part camera, 36 operation panel, 37 communication section, 38 slot, 39 connection section, 40 preparation device, 41 preparation control section, 42 preparation storage section, 43 correspondence information, 44 fixing section, 45 preparation capturing section, 46 drive section, 47 acquisition section, 48 communication section, 49 preparation table, 50 feeder (component supply device), 51 supply control section, 52 supply storage section, 53 supply identification information, 54 reel, 55 holding member, 56 accommodating section, 57 reel identification information, 58 connector, 59 feeding mechanism, 59a feeding hole, 60 management PC, 61 management control section, 62 management storage section, 63 correspondence information, 66 display section, 67 input device, 68 communication section, 70 component-absent captured image, 71 component-present captured image, 99 network, F feeding direction, P component, S board, W worker

1. A preparation device used in a mounting system including a mounting device configured to perform a process of mounting a component on a processing target, the preparation device comprising:
a fixing section configured to fix a component supply device to which a holding member configured to hold the component is attached and feed the holding member;
a preparation capturing section configured to capture an image of the holding member fixed to the fixing section; and
a preparation control section configured to execute an initial setting process of the holding member by using a captured image captured by the preparation capturing section and cause a storage section to store correspondence information that associates a captured image including a region of the holding member captured by the preparation capturing section in which the component is present and/or a feature value with identification information of the component supply device, and/or correspondence information that associates a captured image including a region of the holding member captured by the preparation capturing section in which the component is not present and/or a feature value with the identification information of the component supply device.

2. The preparation device according to claim 1, wherein
the preparation control section causes the storage section to store the captured image captured by the preparation capturing section as the captured image including the region of the holding member in which the component is not present, and causes the storage section to store a captured image captured by feeding the holding member and having a changed feature value as the captured image including the region of the holding member in which the component is present.

3. The preparation device according to claim 1 or 2, wherein
the component supply device includes a supply storage section configured to store the identification information of the component supply device,
the fixing section is electrically connectable to the component supply device, and
the preparation control section acquires the identification information output from the supply storage section.

4. The preparation device according to any one of claims 1 to 3, wherein
the preparation control section acquires identification information of the holding member and the identification information of the component supply device to store the identification information of the holding member and the identification information of the component supply device in the storage section in association with each other.

5. A mounting device connected to the preparation device according to any one of claims 1 to 4 via an electric communication line, the mounting device comprising:
an attachment section configured to attach the component supply device;
a mounting capturing section configured to capture an image of the holding member attached to the attachment section;
a mounting section configured to execute a mounting process of collecting the component from the component supply device attached to the attachment section to dispose the component on the processing target; and
a mounting control section configured to acquire the correspondence information corresponding to the component supply device attached to the attachment section from the storage section to determine whether the component remains in the component supply device based on the acquired correspondence information and a captured image captured by the mounting capturing section.

6. The mounting device according to claim 5, wherein
after a collection error of the component by the mounting section occurs, the mounting control section determines whether any components remain in a component supply device where the collection error has occurred.

7. A mounting system comprising:
the preparation device according to any one of claims 1 to 4; and
the mounting device according to claim 5 or 6.

8. An information processing method executed by a preparation device used in a mounting system including a mounting device configured to perform a process of mounting a component on a processing target and having a fixing section configured to fix a component supply device to which a holding member configured to hold the component is attached and feed the holding member and a preparation capturing section configured to capture an image of the holding member fixed to the fixing section, the information processing method comprising:
(a) a step of executing an initial setting process of the holding member by using a captured image captured by the preparation capturing section; and
(b) a step of storing correspondence information that associates a captured image including a region of the holding member captured by the preparation capturing section in which the component is present and/or a feature value with identification information of the component supply device, and/or correspondence information that associates a captured image including a region of the holding member captured by the preparation capturing section in which the component is not present and/or a feature value with the identification information of the component supply device in a storage section.
